(19) United States
(12) Patent Application Publication
(10) Pub. No.: US 2001/0016001 A1
(43) Pub. Date: Aug. 23, 2001

(54) Arrangement for filtering digital data

(75) Inventors: Michael Berg, Hamburg (DE); Winfried Gehrke, Neu Wulmsdorf (DE)

Correspondence Address: Corporate Patent Counsel, U.S. Philips Corporation;, 580 White Plains Road, Tarrytown, NY, 10591, US

(73) Assignee: U. S. Philips Corporation

(21) Appl. No.: 09/766,751

(22) Filed: Jan. 22, 2001

(30) Foreign Application Priority Data
Jan. 25, 2000 (DE) 10002964.7

(51) Int. Cl. H03K 5/159; H03H 7/30; H03H 7/40

(52) U.S. Cl. 375/229

(57) ABSTRACT

In a filter arrangement for filtering digital data comprising synchronizing information, in which the arrangement operates in a system clock, an orderly data transfer for a rapid synchronization after disturbance of the data is ensured in that the arrangement comprises a first filter (1) and a second, succeeding filter (2) which supplies the output signal of the arrangement, in that the first filter (1) receives at least the synchronizing information comprised in the data and the second filter (2) receives the output signal of the first filter (1) as well as the digital data, in that the first filter (1) searches synchronizing information in a cyclically repeating process, passes on this information to its output, subsequently blocks all possibly occurring synchronizing information during a predetermined number of system clock pulses, and, after finishing the predetermined number of system clocks, again searches and passes on the next synchronizing information, and in that the second filter (2) takes over a predetermined number of data from the data signal in a cyclically repeating process from synchronizing information supplied by the first filter (1), and passes on these data to its output and blocks subsequent data until the next synchronizing information supplied by the first filter (1), from which synchronizing information the predetermined number of data is taken over again from the data signal and passed on to the output.

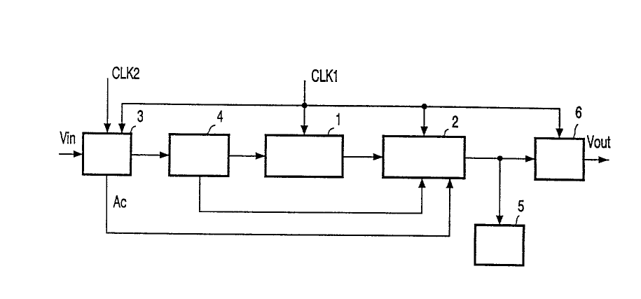

The invention relates to a filter arrangement for filtering digital data comprising synchronizing information, in which the arrangement operates in a system clock.

When digital data are present in a first clock and when these data are to be further processed in a second clock by a device, and when it is further assumed that the two clocks are not coupled together, then the problem arises at the interface between the circuit elements which operate with the first and the second clock that the transfer of data may not succeed completely so that not all data are taken over. The problem may also arise that data are taken over twice.

When, for example, in video data, synchronizing information is comprised in such data, the data are to be taken over in an ordered manner in accordance with the synchronizing information because they can only be further processed in this way. In video data it is important that the data are taken over in the second clock in a field-wise and/or line-wise ordered manner. Moreover, there is the problem that data units/packets characterized by synchronizing signals, for example, video fields or frames in video data, are possibly supplied more rapidly by the first clock than they can be processed in the second clock. Then parts of the video data or whole blocks must be left out.

It is an object of the invention to provide an arrangement for filtering such data which overcomes the above-mentioned problems and is also capable, after data disturbances in which the data do not occur in the desired order, of nevertheless making them subsequently available again in an ordered manner in accordance with the synchronizing information.

According to the invention, this object is achieved in that the arrangement comprises a first filter and a second, succeeding filter which supplies the output signal of the arrangement, in that the first filter receives at least the synchronizing information comprised in the data and the second filter receives the output signal of the first filter as well as the digital data, in that the first filter searches synchronizing information in a cyclically repeating process, passes on this information to its output, subsequently blocks all possibly occurring synchronizing information during a predetermined number of system clock pulses, and, after finishing the predetermined number of system clocks, again searches and passes on the next synchronizing information, and in that the second filter takes over a predetermined number of data from the data signal in a cyclically repeating process from synchronizing information supplied by the first filter, and passes on these data to its output and blocks subsequent data until the next synchronizing information supplied by the first filter, from which synchronizing information the predetermined number of data is taken over again from the data signal and passed on to the output.

The arrangement has two filters, both of which operate in the system clock. The synchronizing information comprised in the data is applied to the first filter. The output signal of the first filter, i.e. the filtered synchronizing information, and the digital data are applied to the second filter.

The first filter operates in a cyclically repeating process. After take-over of synchronizing information from the input signal applied to the filter, no new synchronizing information is subsequently taken over any longer during a predetermined number of system clock pulses. This means that the filter blocks and does not apply any synchronizing information possibly occurring in the input signal in this time interval to its output. Only after finishing the predetermined number of system clock pulses will the next synchronizing information be taken over again, i.e. passed on to the output of the filter. Now, the process repeats itself so that again the first filter blocks during the predetermined number of system clock pulses, i.e. possibly occurring synchronizing information is not passed on to its output. Only after this time interval has finished will the next synchronizing pulse be taken over again. This process is repeated cyclically.

As a result, it is achieved that the first filter only passes synchronizing pulses when they have a minimum mutual time interval. It is thereby achieved that, when the data flow is too large, only synchronizing information, which complies with this minimum condition, is taken over.

The second filter also operates in a cyclically repeating process. When the first filter supplies synchronizing information to the second filter, this filter subsequently takes over a predetermined number of data from the data signal. In this case, there is thus no orientation of the number of system clock pulses but the second filter is oriented towards the number of data. When the second filter has taken over the predetermined number of data after the synchronizing information, the filter subsequently blocks, i.e. it does not pass on any further data to its output. Only when the first filter supplies the next synchronizing information will the second filter subsequently take over the predetermined number of data from the data signal and subsequently blocks again until the next synchronizing information supplied by the first filter occurs.

It is thereby achieved that each data packet is completed before a new one is started. Superfluous data are canceled. Thus, a data format of the desired form is always available at the output of the second filter. The data format is such that synchronizing information always follows a given data quantity which in turn is followed by the next synchronizing information.

For example, for video data, this processing mode is important because only in this way the required picture structure can be guaranteed.

Such a filter is particularly useful when the data flow applied to the filter arrangement is taken over in a clock by another signal whose clock is not coupled to the take-over clock.

In accordance with an embodiment of the invention as defined in claim 2, a separating stage is provided which ensures that the first filter exclusively receives the synchronizing information.

A further embodiment of the invention as defined in claim 3 relates to the case where the data are applied to the arrangement in an external clock which is not coupled to the system clock. An acquisition stage acquires the data in the system clock and determines with which pulses of the system clock a valid data bit of the data present in the external uncoupled clock is provided. Whenever such a valid data bit occurs, a corresponding acquisition signal is applied to the second filter. It is thereby ensured that the second filter only takes over a new data when this is valid and when it does not actually correspond to the previous data, for example, due to double scanning.

In accordance with a further embodiment of the invention as defined in claim 4, the number of system clock pulses during which the first filter blocks is implemented in such a way that the filter arrangement only takes over as many data as can be processed in subsequent processes. Furthermore, the predetermined number of data taken over by the second filter after occurrence of synchronizing information is implemented in such a way that all data between two consecutive synchronizing information components are taken over by the filter arrangement when the external clock has a nominal clock frequency. In the normal case, i.e. when the external data are present in the nominal frequency, a complete data transfer is thereby ensured.

In accordance with further embodiments of the invention as defined in claims 5, 6 and 7, the arrangement according to the invention may be preferably used for processing video data. In this case, it is advantageous that the first filter evaluates the vertical synchronizing information comprised as synchronizing information in the video data so that, by means of the first filter, an ordered division in accordance with fields takes place. After a disturbed data flow, an ordered take-over video data is then again achieved, starting with the next field. However, the second filter evaluates the horizontal and vertical synchronizing pulses in the video data in addition to the synchronizing information supplied by the first filter. It is thereby achieved that the second filter additionally performs a fine sorting in accordance with the picture lines.

These properties of the filter arrangement in processing video data may advantageously be used for further subsequent encoding of the video data, as in further embodiments of the invention as defined in claims 8 and 9. For such an encoding, it is important, particularly after a disturbed video signal flow, that the data are possibly rapidly present in an ordered form again in dependence upon the synchronizing information. It is particularly advantageous in this respect to buffer the data supplied by the second filter in a memory from which the encoding process then takes the data.

These and other aspects of the invention are apparent from and will be elucidated with reference to the embodiments described hereinafter.

In the drawing:

The sole FIGURE is a block diagram of an arrangement according to the invention, comprising a first filter 1 and a subsequent second filter 2. Both filters 1 and 2 are clocked by means of a system clock CLK1.

The input signal of the circuit arrangement is a video signal Vin which is present in an external clock CLK2 which is not coupled to the system clock CLK1. The video data Vin are applied to an acquisition stage 3 which supplies the video data in the system clock CLK1 at the output. The acquisition stage thus scans the data again while it determines for each system clock pulse of the system clock CLK1 whether a new valid data of the video data Vin in the first external clock CLK2 is present. Whenever this is the case, a corresponding pulse in an acquisition signal Ac is applied to the second filter 2. It is thereby achieved that the second filter 2 only takes over valid new data.

The acquisition stage 3 precedes a separating stage 4 which separates the data flow present in the system clock and as supplied by the acquisition stage 3 into the synchronizing information and the real data. The synchronizing information is applied to the input of the first filter 1. The data are applied to the second filter 2. In this embodiment, the separating stage not only filters the synchronizing information to be evaluated by the first filter 1, namely the vertical synchronizing pulses comprised in the video data Vin, but also horizontal synchronizing pulses comprised in the video data Vin which are passed on by the first filter 1 to the second filter 2.

The second filter 2 supplies the filtered data at its output, which data are applied to a memory 5 in which they are buffered. A subsequent encoding process 6 which, for example, converts the data into MPEG encoded data, which then represent the output signal Vout, takes the data from the buffer memory 5. This encoding process 6, which also operates in the system clock CLK1, will not be further elucidated hereinafter because it is not a subject of the invention.

The operation of the first filter and the second filter 2 will be elucidated hereinafter.

The synchronizing information filtered from the digital data by means of the separating stage 4, as well as horizontal synchronizing pulses are applied to the first filter 1. In the embodiment, the first filter 1 evaluates only the vertical synchronizing pulses as synchronizing information. When such a vertical synchronizing pulse occurs in the video data, the first filter 1 takes over this pulse and passes it on at its output. All subsequent synchronizing information is blocked during a predetermined number of system clock pulses of the system clock CLK1, i.e. it is not passed on to the output of the filter 1 and hence to the filter 2. Only when the predetermined number of system clock pulses has finished will the next occurring vertical synchronizing pulse be subsequently taken over again and passed on to the second filter 2.

The predetermined number of pulses of the system clock CLK1 is implemented in such a way that the encoding process 6 can completely process data in this number of clocks.

The second filter 2 orients itself by the vertical synchronizing information supplied by the first filter 1.

When such synchronizing information from the first filter is taken over by the second filter 2, the second filter 2 subsequently takes over a predetermined number of data from the separating stage 4, as well as horizontal synchronizing pulses from filter 1. The filter 2 orients itself to the acquisition signal Ac of the acquisition stage 3 so that only valid data are taken over.

The filter 2 also operates in a cyclically repeating process, i.e. after every valid synchronizing information as supplied by the first filter 1, the predetermined number of data is taken over. Subsequently, blocking takes place as long as new synchronizing information is supplied by the first filter 1 again.

It is thereby ensured that, after every synchronizing information, a predetermined number of data occurs in the output signal of the second filter 2. An ordering of the data is thereby achieved which can thus be stored in an ordered form in the buffer memory 5.

Moreover, it is possible that the second filter does not only evaluate the synchronizing information (vertical synchronizing pulses) supplied by the first filter 1 but also the horizontal synchronizing pulses comprised in the video data and supplied by the first filter 1 and/or the separating stage 4. The second filter can thus store the data not only in accordance with fields but also in accordance with lines in an ordered manner in the buffer memory 5.

It should thus be noted that the first filter filters the synchronizing information and orients itself to the system clock, but that the second filter takes over the data of a predetermined quantity in an ordered form in accordance with the synchronizing information as supplied by the first filter. The second filter thus does not orient itself to the system clock but to the data quantity.

The number of predetermined data taken over by the second filter 2 after occurrence of synchronizing information is oriented to the number of data occurring in a field of a video signal. As a result, the arrangement supplies the data at the output, also after a disturbance, in an ordered form as quickly as possible again for storage in the memory 5 and for further processing in the encoding process. After a disturbance or a drop-out of data, a possibly rapid up-synchronization of the encoding process is thereby achieved, so that the disturbed mode of operation of the encoding process 6, which would occur in the case of disturbed data, is eliminated again as quickly as possible.

In practice, such problems may occur when the video data occurring at the input originate, for example, from a video recorder which operates in a special mode. Data then no longer occur in the data stream with a correct time base or are disturbed or even incomplete. This disturbed data stream is changed into a nominal structure again by the filter arrangement according to the invention. When the video recorder is changed from its special mode to the normal operating mode, the filter according to the invention ensures that the data are again passed on in an ordered way and without disturbances to the encoding process 6.

1. A filter arrangement for filtering digital data comprising synchronizing information, in which the arrangement operates in a system clock, characterized in that the arrangement comprises a first filter (1) and a second, succeeding filter (2) which supplies the output signal of the arrangement, in that the first filter (1) receives at least the synchronizing information comprised in the data and the second filter (2) receives the output signal of the first filter (1) as well as the digital data, in that the first filter (1) searches synchronizing information in a cyclically repeating process, passes on this information to its output, subsequently blocks all possibly occurring synchronizing information during a predetermined number of system clock pulses, and, after finishing the predetermined number of system clocks, again searches and passes on the next synchronizing information, and in that the second filter (2) takes over a predetermined number of data from the data signal in a cyclically repeating process from synchronizing information supplied by the first filter (1), and passes on these data to its output and blocks subsequent data until the next synchronizing information supplied by the first filter (1), from which synchronizing information the predetermined number of data is taken over again from the data signal and passed on to the output.

2. An arrangement as claimed in claim 1, characterized in that the arrangement comprises a separating stage (4) which separates the synchronizing information applied to the first filter (1) from the digital data.

3. An arrangement as claimed in claim 1, characterized in that the data of an acquisition stage (3) provided in the arrangement are supplied in a first external clock which is not coupled to the system clock, and in that the acquisition stage (3) determines with which pulses of the system clock a valid new data bit of the serial data is present, and which applies a corresponding acquisition signal to the second filter (2).

4. An arrangement as claimed in claims 1 and 3, characterized in that the predetermined number of system clock pulses is implemented in such a way that processes succeeding the filter arrangement can still process the data rate of the output signal of the arrangement, and in that the predetermined number of data is implemented in such a way that all data between two synchronizing information components are taken over when the external clock has a nominal clock frequency.

5. An arrangement as claimed in claim 1, characterized in that the data are video data which are present in the form of data words.

6. An arrangement as claimed in claim 5, characterized in that the first filter (1) evaluates vertical synchronizing pulses comprised as synchronizing information in the video data.

7. An arrangement as claimed in claim 5, characterized in that the second filter (2) evaluates the vertical synchronizing pulses supplied by the first filter as synchronizing information and additionally orders the data in dependence upon horizontal synchronizing pulses.

8. An arrangement as claimed in claim 1, characterized in that the arrangement precedes a memory (5) in which the output data of the second filter (2) are stored in an ordered manner in dependence upon the synchronizing information.

9. An arrangement as claimed in claim 8, characterized in that the arrangement precedes an MPEG encoding process (6) which accesses the data stored in the memory (5), and in that the second filter (2) supplies a filling level signal indicating the filling level of the data in the memory (5) for the MPEG encoding process (6).
